(19) United States
(12) Patent Application Publication
(10) Pub. No.: US 2025/0285568 A1
(43) Pub. Date: Sep. 11, 2025

(54) METHOD OF TESTING COMPENSATION OPERATION AND COMPENSATION OPERATION TEST SYSTEM PERFORMING THE SAME

(71) Applicant: Samsung Display Co., LTD., Yongin-si (KR)

(72) Inventor: DONGBEOM CHO, Yongin-si (KR)

(21) Appl. No.: 18/966,226

(22) Filed: Dec. 3, 2024

(30) Foreign Application Priority Data
Mar. 5, 2024 (KR) 10-2024-0031619

(51) Int. Cl. G09G 3/00

(52) U.S. Cl. CPC G09G 3/006; G09G 2320/0233; G09G 2330/12

(57) ABSTRACT

A method of testing a compensation operation for a display device includes providing test data including red test data, green test data, and blue test data to the display device, capturing an image displayed by the display device based on the test data, generating red compensation data which is compensation data for the red test data, green compensation data which is compensation data for the green test data, and blue compensation data which is compensation data for the blue test data based on a luminance and a color coordinates of the captured image, and comparing a delta value, calculated based on red test data to which the red compensation data is applied, green test data to which the green compensation data is applied, and blue test data to which the blue compensation data is applied, with a threshold value to test whether the compensation operation is a miscompensation.

### BACKGROUND

This application claims priority to Korean Patent Application No. 10-2024-0031619 filed on Mar. 5, 2024, and all the benefits accruing therefrom under 35 U.S.C. § 119, the content of which in its entirety is herein incorporated by reference.

### 1. Field

Embodiments of the present invention relates to a method of testing a compensation operation and a compensation operation test system performing the same. More particularly, the present invention relates to a method of testing a compensation operation for a display device and a compensation operation test system performing the same.

### 2. Description of the Related Art

A display device may include pixels and display an image using the pixels. However, even if the display device is formed by the same process, the display device may have different brightness or stains (i.e., mura) due to process deviation, etc. (i.e., internal factors of the display device).

In order to remove the stains and improve the brightness uniformity, a mura-compensation algorithm operation that compensates for the display device in terms of brightness and color coordinates may be performed, or a multi-time programming (“MTP”) operation that repeatedly compensates for the display device in terms of brightness and color coordinates may be performed.

However, even if the mura-compensation algorithm operation or the multi-time programming operation is performed, the compensation operation for the display device may not be accurately performed due to an error of a camera that captures the image displayed by the display device, static electricity of the display device, foreign matter in the camera or the display device, etc. (i.e., external factors of the display device).

### SUMMARY

Embodiments of the present invention provide a method of testing a compensation operation for a display device.

Embodiments of the present invention provide a compensation operation test system performing the method.

In an embodiment of a method of testing a compensation operation for a display device according to the present invention, the method includes providing test data including first red test data, first green test data, and first blue test data to the display device, capturing an image displayed by the display device based on the test data, generating red compensation data which is compensation data for the first red test data, green compensation data which is compensation data for the first green test data, and blue compensation data which is compensation data for the first blue test data based on a luminance and a color coordinates of the captured image, and comparing a delta value, calculated based on second red test data to which the red compensation data is applied, second green test data to which the green compensation data is applied, and second blue test data to which the blue compensation data is applied, with a threshold value to test whether the compensation operation is a miscompensation.

In an embodiment, the delta value may be a difference between a maximum value and a minimum value among the second red test data to which the red compensation data is applied, the second green test data to which the green compensation data is applied, and the second blue test data to which the blue compensation data is applied.

In an embodiment the comparing of the delta value with the threshold value may include determining that the compensation operation is the miscompensation when the delta value is greater than the threshold value.

In an embodiment the comparing of the delta value with the threshold value may further include determining that the compensation operation is a normal compensation when the delta value is less than or equal to the threshold value.

In an embodiment, the display device may include a substrate, a circuit layer positioned on the substrate, and a display layer positioned on the circuit layer.

In an embodiment, the delta value may be a delta value of the circuit layer, and the threshold value may be a threshold value of the circuit layer.

In an embodiment, the delta value may be a delta value of the display layer, and the threshold value may be a threshold value of the display layer.

In an embodiment, the display device may be divided into cells.

In an embodiment, the delta value may be a delta value of each of the cells, and the threshold value may be a threshold value of each of the cells.

In an embodiment, the delta value may be calculated based on a production date of the display device.

In an embodiment, the delta value may be calculated based on a process duration of the display device.

In an embodiment of a compensation operation test system according to the present invention, the compensation operation test system includes a display device including a display panel including pixels, and a test device configured to perform a compensation operation and test the compensation operation. The test device includes a test data generator, a camera, a compensation data generator, and a compensation operation tester. The test data generator is configured to provide test data including first red test data, first green test data, and first blue test data to the display device. The camera is configured to capture an image displayed by the display device based on the test data. The compensation data generator is configured to generate red compensation data which is compensation data for the first red test data, green compensation data which is compensation data for the first green test data, and blue compensation data which is compensation data for the first blue test data based on a luminance and a color coordinates of the captured image. The compensation operation tester is configured to compare a delta value, calculated based on second red test data to which the red compensation data is applied, second green test data to which the green compensation data is applied, and second blue test data to which the blue compensation data is applied, with a threshold value to test whether the compensation operation is a miscompensation

In an embodiment, the delta value may be a difference between a maximum value and a minimum value among the red test data to which the second red compensation data is applied, the second green test data to which the green compensation data is applied, and the second blue test data to which the blue compensation data is applied.

In an embodiment the compensation operation tester may determine that the compensation operation is the miscompensation when the delta value is greater than the threshold value.

In an embodiment the compensation operation tester may determine that the compensation operation is a normal compensation when the delta value is less than or equal to the threshold value.

In an embodiment, the display device may include a substrate, a circuit layer positioned on the substrate, and a display layer positioned on the circuit layer.

In an embodiment, the delta value may be a delta value of the circuit layer, and the threshold value may be a threshold value of the circuit layer.

In an embodiment, the delta value may be a delta value of the display layer, and the threshold value may be a threshold value of the display layer.

In an embodiment, the display device may be divided into cells.

In an embodiment, the delta value may be a delta value of each of the cells, and the threshold value may be a threshold value of each of the cells.

According to the method and the compensation operation test system, by comparing the delta value calculated based on the red test data to which the red compensation data is applied, the green test data to which the green compensation data is applied, and the blue test data to which the blue compensation data is applied, with the threshold value, it may be tested whether the compensation operation is the miscompensation. Accordingly, when the compensation operation is the miscompensation, it is determined that there is a problem (e.g., an external factor of the display device 100) in the compensation operation, and thus the compensation data may not be applied to the display device.

### BRIEF DESCRIPTION OF THE DRAWINGS

The above and other features of embodiments of the present invention will become more apparent by describing in detailed embodiments thereof with reference to the accompanying drawings, in which:

FIG. 1 is a block diagram illustrating a compensation operation test system according to embodiments of the present invention;

FIG. 2 is a block diagram illustrating a display device of FIG. 1;

FIG. 3 is a circuit diagram illustrating a pixel of FIG. 2;

FIG. 4 is a cross-sectional view illustrating a display device of FIG. 1;

FIG. 5 is a plan view illustrating cells constituting a display device of FIG. 1;

FIG. 6 is a diagram explaining an operation for testing whether a compensation operation for a display device of FIG. 1 is a miscompensation;

FIG. 7 is a flowchart illustrating a method of testing a compensation operation according to embodiments of the present invention;

FIG. 8 is a block diagram illustrating an electronic device; and

FIG. 9 is a diagram illustrating an embodiment in which the electronic device of FIG. 8 is implemented as a smart phone;

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “on” another element, it can be directly on the other element or intervening elements may be present therebetween. In contrast, when an element is referred to as being “directly on” another element, there are no intervening elements present. Hereinafter, the present invention will be described in more detail with reference to the accompanying drawings.

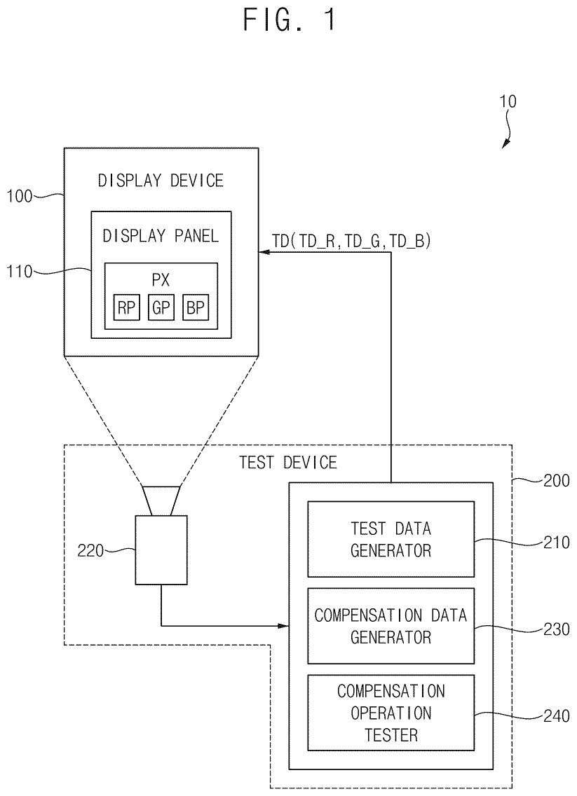

FIG. 1 is a block diagram illustrating a compensation operation test system 10 according to embodiments of the present invention.

Referring to FIG. 1, a compensation operation test system 10 according to embodiments of the present invention may include a display device 100 and a test device 200. The display device 100 may display an image. The test device 200 may perform a compensation operation (e.g. a mura compensation algorithm operation or a multi-time programming operation) for the display device 100 based on the image displayed by the display device 100, and may test whether the compensation operation is a normal compensation or a miscompensation.

The display device 100 may receive test data TD from the test device 200, and the test data TD may include first red test data TD_R, first green test data TD_G, and first blue test data TD_B.

The display device 100 may include a display panel 110, and the display panel 110 may include pixels PX. Each of the pixels PX may include a red sub-pixel RP, a green sub-pixel GP, and a blue sub-pixel BP.

The red sub-pixel RP may emit a red light based on the first red test data TD_R, the green sub-pixel GP may emit a green light based on the first green test data TD_G, and the blue sub-pixel BP may emit a blue light based on the first blue test data TD_B. A mixed light of the red light, the green light, and the blue light represents various colors. Therefore, the display device 100 may emit an image representing the various colors using the red sub-pixel RP, the green sub-pixel GP, and the blue sub-pixel BP.

The test device 200 may include a test data generator 210, a camera 220, a compensation data generator 230, and a compensation operation tester 240.

The test data generator 210 may generate the test data TD. The display device 100 may display the image based on the test data TD. The camera 220 may capture the image displayed by the display device 100. In an embodiment, the camera 220 may be a Charge Coupled Device (“CCD”) camera or any other suitable camera.

The compensation data generator 230 may calculate a luminance and a color coordinates of the captured image displayed by the display device 100 based on the captured image. The compensation data generator 230 may perform the compensation operation of generating compensation data based on the luminance and the color coordinates of the captured image displayed by the display device 100. The compensation data may include red compensation data for the first red test data TD_R, green compensation data for the first green test data TD_G, and blue compensation data for the first blue test data TD_B. The compensation data may be applied to the test data TD and repeatedly performed until the luminance and the color coordinates of the captured image reach a target luminance and a target color coordinates.

The compensation operation tester 240 may test whether the compensation operation is the normal compensation or the miscompensation based on the compensation data. For example, the compensation operation tester 240 may compare a delta value, which is a difference between a maximum value and a minimum value among second red test data TD_R to which the red compensation data is applied, second green test data TD_G to which the green compensation data is applied, and second blue test data TD_B to which the blue compensation data is applied, with a threshold value to test whether the compensation operation is the normal compensation or the miscompensation. When the compensation operation is the normal compensation, the compensation data may be applied to the display device 100. However, when the above compensation operation is the miscompensation, the compensation operation tester 240 may determine that there is a problem with the compensation operation, and thus the compensation data may not be applied to the display device 100.

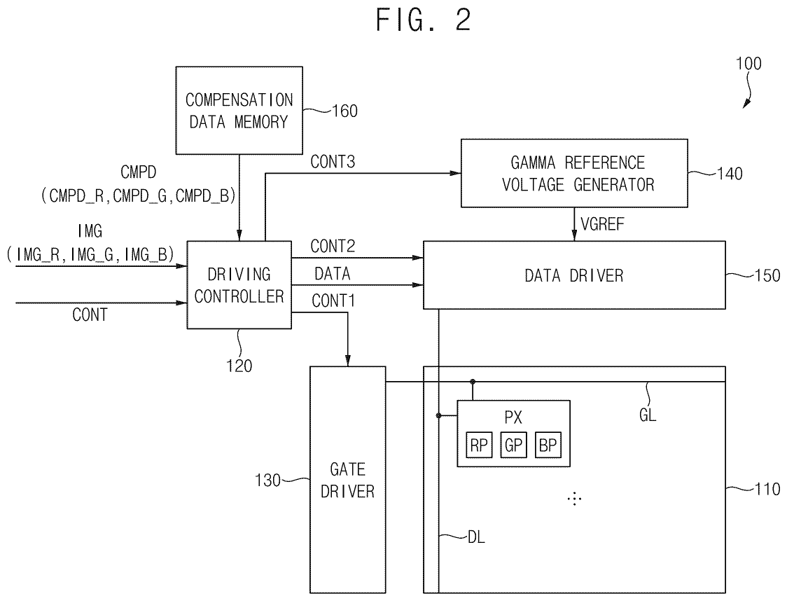

FIG. 2 is a block diagram illustrating a display device 100 of FIG. 1.

Referring to FIGS. 1 and 2, the display device 100 may include the display panel 110 and a display panel driver. The display panel driver may include a driving controller 120, a gate driver 130, a gamma reference voltage generator 140, a data driver 150, and a compensation data memory 160.

The display panel 110 may include a display area for displaying an image and a peripheral area disposed adjacent to the display area.

The display panel 110 may include gate lines GL, data lines DL, pixels PX electrically connected to the gate lines GL and the data lines DL, respectively. The gate lines GL may extend in a first direction, and the data lines DL may extend in a second direction crossing the first direction.

The driving controller 120 may receive input image data IMG and an input control signal CONT from an external device (not shown). For example, the input image data IMG may include red image data IMG_R, green image data IMG_G and blue image data IMG_B. The input image data IMG may include white image data. The input image data IMG may include magenta image data, yellow image data, and cyan image data. The input control signal CONT may include a master clock signal and a data enable signal. The input control signal CONT may further include a vertical synchronization signal and a horizontal synchronization signal.

The driving controller 120 may generate a first control signal CONT1, a second control signal CONT2, a third control signal CONT3, and a data signal DATA based on the input image data IMG and the input control signal CONT.

The driving controller 120 may generate the first control signal CONT1 for controlling an operation of the gate driver 130 based on the input control signal CONT, and output the first control signal CONT1 to the gate driver 130. The first control signal CONT1 may include a vertical start signal and a gate clock signal.

The driving controller 120 may generate the second control signal CONT2 for controlling an operation of the data driver 150 based on the input control signal CONT, and output the second control signal CONT2 to the data driver 150. The second control signal CONT2 may include a horizontal start signal and a load signal.

The driving controller 120 may generate the data signal DATA based on the input image data IMG. The driving controller 120 may output the data signal DATA to the data driver 150.

The driving controller 120 may generate the third control signal CONT3 for controlling an operation of the gamma reference voltage generator 140 based on the input control signal CONT, and output the third control signal CONT3 to the gamma reference voltage generator 140.

The gate driver 130 may generate gate signals for driving the gate lines GL in response to the first control signal CONT1 received from the driving controller 120. The gate driver 130 may output the gate signals to the gate lines GL.

The gamma reference voltage generator 140 may generate a gamma reference voltage VGREF in response to the third control signal CONT3 received from the driving controller 120. The gamma reference voltage generator 140 may provide the gamma reference voltage VGREF to the data driver 150. The gamma reference voltage VGREF may have a value corresponding to each data signal DATA.

In an embodiment, the gamma reference voltage generator 140 may be disposed in the driving controller 120 or may be disposed in the data driver 150.

The data driver 150 may receive the second control signal CONT2 and the data signal DATA from the driving controller 120, and receive the gamma reference voltage VGREF from the gamma reference voltage generator 140. The data driver 150 may convert the data signal DATA into a data voltage having an analog type using the gamma reference voltage VGREF. The data driver 150 may output the data voltage to the data line DL.

The compensation data memory 160 may store the compensation data CMPD generated by the compensation data generator 230 of the test device 200. The compensation data memory 160 may provide the compensation data CMPD to the driving controller 120.

The driving controller 120 may compensate the input image data IMG based on the compensation data CMPD to generate the data signal DATA. For example, the compensation data CMPD may include the red compensation data CMPD_R, the green compensation data CMPD_G, and the blue compensation data CMPD_B, and the red compensation data CMPD_R may be applied to the red image data IMG_R, the green compensation data CMPD_G may be applied to the green image data IMG_G, and the blue compensation data CMPD_B may be applied to the blue image data IMG_B.

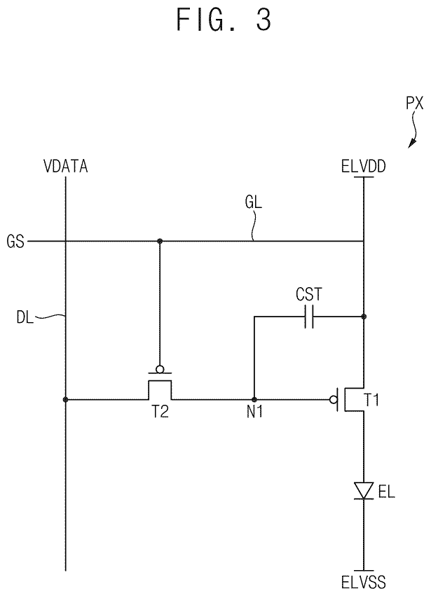

FIG. 3 is a circuit diagram illustrating a pixel PX of FIG. 2.

Referring to FIGS. 1 to 3, the pixel PX may include a first transistor T1, a second transistor T2, and a storage capacitor CST.

The first transistor T1 may include a gate electrode connected to a first node N1, a first electrode connected to a first power line transmitting a first power voltage ELVDD, and a second electrode connected to a light emitting element EL. The first transistor Tl may generate a driving current based on a voltage difference between the gate electrode and the first electrode.

The second transistor T2 may include a gate electrode connected to the gate line GL transmitting the gate signal GS, a first electrode connected to the data line DL transmitting the data voltage VDATA, and a second electrode connected to the first node N1. The second transistor T2 may provide the data voltage VDATA to the first node N1 in response to the gate signal GS.

The storage capacitor CST may include a first electrode connected to the first node N1 and a second electrode connected to the first power line. The storage capacitor CST may maintain the voltage difference between the gate electrode of the first transistor T1 and the first electrode.

The light emitting element EL may include an anode connected to the second electrode of the first transistor T1 and a cathode connected to a second power line transmitting a second power voltage ELVSS. The light emitting element EL may emit a light based on the driving current. A luminance of the light emitting element EL may be determined based on an intensity of the driving current. The intensity of the driving current may be determined based on a level of the data voltage VDATA.

Although FIG. 3 shows an embodiment in which the first transistor Tl and the second transistor T2 are P-type transistors (e.g., PMOS transistors, especially low-temperature polycrystalline silicon (“LTPS”) transistors), the present invention is not limited thereto. In another embodiment, at least one of the first transistor T1 and the second transistor T2 may be an N-type transistor (e.g., NMOS transistor).

Although FIG. 3 shows an embodiment in which the pixel PX includes two transistors and one capacitor, the present invention is not limited thereto. In another embodiment, the pixel PX may include at least three transistors and/or at least two capacitors.

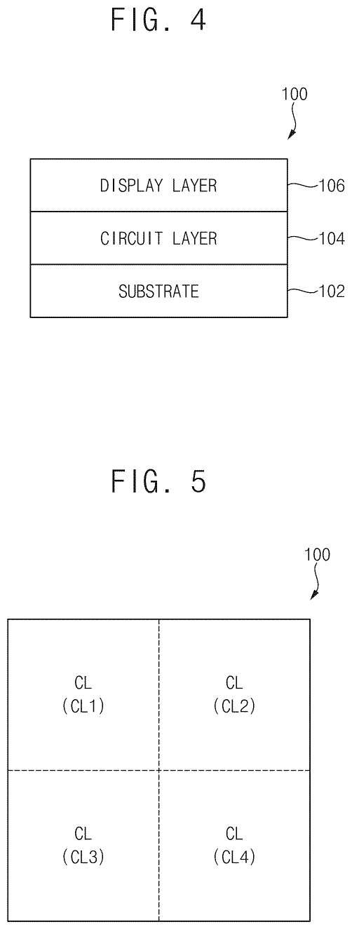

FIG. 4 is a cross-sectional view illustrating a display device 100 of FIG. 1.

Referring to FIGS. 1 to 4, the display device 100 may include a substrate 102, a circuit layer 104 positioned on the substrate 102, and a display layer 106 positioned on the circuit layer 104. The display device 100 may be formed by stacking the substrate 102, the circuit layer 104, and the display layer 106. The circuit layer 104 may include the gate lines GL, the data lines DL, and the transistors T1, T2. The display layer 106 may be collectively referred to as a layer formed by an evaporation process and a thin film encapsulation process, and may include a light emitting element layer and an encapsulation layer sealing the same. The light emitting element layer may include the light emitting element EL.

FIG. 5 is a plan view illustrating cells CL constituting a display device 100 of FIG. 1.

Referring to FIGS. 1 to 5, the display device 100 may be formed by stacking the substrate 102, the circuit layer 104, and the display layer 106, and the display device 100 may be divided into cells CL. When the electronic device is a notebook or tablet PC, a number of the cells CL may be several to several tens, and when the electronic device is a smartphone or a smart watch, the number of the cells CL may be several tens to several hundred. For example, the cells CL may include first to fourth cells CL1 to CL4.

Meanwhile, even if the display device 100 is formed by a same process, the display device 100 may have a different luminance or a stain (i.e., mura) due to a process deviation, etc. For example, the display device 100 may have a different luminance or a stain due to a process deviation of the circuit layer 104 or the display layer 106 (i.e., an internal factor of the display device 100). In addition, the display device 100 may have a different brightness or a stain due to a process deviation of the cells CL.

In order to remove the stain and improve a brightness uniformity, a mura compensation algorithm operation which compensates for the display device 100 in terms of a luminance and a color coordinates may be performed, or a multi-time programming operation which repeatedly compensates the display device 100 in terms of the luminance and the color coordinates may be performed.

However, due to an error of the camera 220 which captures the image displayed by the display device 100, a static electricity of the display device 100, a foreign matter of the camera 220 or the display device 100, etc. (i.e., external factors of the display device 100), even if the mura compensation algorithm operation or the multi-time programming operation is performed, the compensation operation for the display device 100 may not be performed accurately.

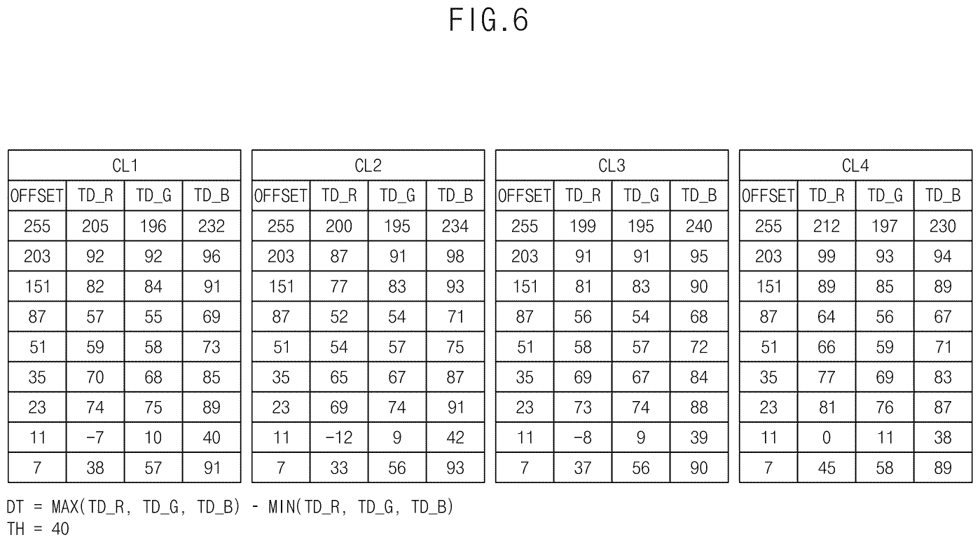

FIG. 6 is a diagram explaining an operation for testing whether a compensation operation for a display device 100 of FIG. 1 is a miscompensation.

Referring to FIGS. 1 to 6, the display device 100 may be divided into the cells CL, and each of the cells CL may have a different characteristics. Therefore, the compensation data generator 230 of the test device 200 may generate the red compensation data CMPD_R, the green compensation data CMPD_G, and the blue compensation data CMPD_B by considering the characteristics of the each of the cells CL to compensate the red test data TD_R, the green test data TD_G, and the blue test data TD_B.

The compensation operation tester 240 may compare a delta value DT, which is a difference between a maximum value and a minimum value among red test data TD_R to which the red compensation data CMPD_R is applied, green test data TD_G to which the green compensation data CMPD_G is applied, and blue test data TD_B to which the blue compensation data CMPD_B is applied, with a threshold value TH to test whether the compensation operation is the normal compensation or the miscompensation. A formula of the delta value DT may be “DT=MAX(TD_R, TD_G, TD_B)−MIN(TD_R, TD_G, TD_B)”. Here, DT is the delta value, MAX(TD_R, TD_G, TD_B) is the maximum value among the red test data TD_R to which the red compensation data CMPD_R is applied, the green test data TD_G to which the green compensation data CMPD_G is applied, and the blue test data TD_B to which the blue compensation data CMPD_B is applied, and MIN(TD_R, TD_G, TD_B) is the minimum value among the red test data TD_R to which the red compensation data CMPD_R is applied, the green test data TD_G to which the green compensation data CMPD_G is applied, and the blue test data TD_B to which the blue compensation data CMPD_B is applied.

For example, when the delta value DT is greater than the threshold value TH, the compensation operation tester 240 may determine that the compensation operation is the miscompensation. For example, when the delta value DT is less than or equal to the threshold value TH, the compensation operation tester 240 may determine that the compensation operation is the normal compensation.

For example, as shown in FIG. 5, the cells CL may include the first to fourth cells CL1 to CL4. Each of the first to fourth cells CL1 to CL4 may have a different characteristics, and the compensation operation may be performed for the each of the first to fourth cells CL1 to CL4. As shown in FIG. 6, for the each of the first to fourth cells CL1 to CL4, the red test data TD R to which the red compensation data CMPD_R is applied, the green test data TD_G to which the green compensation data CMPD_G is applied, and the blue test data TD_B to which the blue compensation data CMPD_B is applied, for each offset value, may be generated. A target luminance may exist for each grayscale of the test data TD. The offset value may be the grayscale of the test data TD corresponding to the target luminance.

For example, when the offset value is 255 grayscale, a first cell CL1 on which the compensation operation is performed may have red test data TD_R of 205 grayscale, green test data TD_G of 196 grayscale, and blue test data TD_B of 232 grayscale. For example, when the offset value is 255 grayscale, a second cell CL2 on which the compensation operation is performed may have red test data TD_R of 200 grayscale, green test data TD_G of 195 grayscale, and blue test data TD_B of 234 grayscale. For example, when the offset value is 255 grayscale, a third cell CL3 on which the compensation operation is performed may have red test data TD_R of 199 grayscale, green test data TD_G of 195 grayscale, and blue test data TD_B of 240 grayscale. For example, when the offset value is 255 grayscale, a fourth cell CL4 on which the compensation operation is performed may have red test data TD_R of 212 grayscale, green test data TD_G of 197 grayscale, and blue test data TD_B of 230 grayscale.

For example, when the offset value is 255 grayscale, a delta value DT of the first cell CL1 on which the compensation operation is performed may be 36 (=232−196). For example, when the offset value is 255 grayscale, a delta value DT of the second cell CL2 on which the compensation operation is performed may be 39 (=234−195). For example, when the offset value is 255 grayscale, a delta value DT of the third cell CL3 on which the compensation operation is performed may be 45 (=240−195). For example, when the offset value is 255 grayscale, a delta value DT of the fourth cell CL4 on which the compensation operation is performed may be 33 (=230−197).

For example, the threshold value TH may be 40. In this case, since the delta value DT of the first cell CL1 is less than the threshold value TH, the compensation operation for the first cell CL1 may be determined as the normal compensation by the compensation operation tester 240. Since the delta value DT of the second cell CL2 is less than the threshold value TH, the compensation operation for the second cell CL2 may be determined as the normal compensation. Since the delta value DT of the third cell CL3 is greater than the threshold value TH, the compensation operation for the third cell CL3 may be determined as the miscompensation by the compensation operation tester 240. Since the delta value DT of the fourth cell CL4 is less than the threshold value TH, the compensation operation for the fourth cell CL4 may be determined as the normal compensation.

As such, when the delta values DT of the cells CL are less than or equal to the threshold value TH, a difference between the delta values DT of the cells CL is determined to be due to the difference in the characteristics of the each of the cells CL, and thus the compensation operation may be determined to be the normal compensation, but when the delta values DT of the cells CL are greater than the threshold value TH, the cells CL having the delta values DT greater than the threshold value TH may be determined to have the compensation operation as the miscompensation due to external factors of the cells CL.

A test to determine whether the delta values DT of the cells CL are greater than the threshold value TH may be performed not only for an offset value of 255 grayscales, but also for an offset value of 203 grayscale, an offset value of 151 grayscale, an offset value of 87 grayscale, an offset value of 51 grayscale, an offset value of 35 grayscale, an offset value of 23 grayscale, an offset value of 11 grayscale, and an offset value of 7 grayscale.

In FIG. 6, the cells CL are described as a basis, but the characteristic difference does not occur only in the cells CL. The characteristic difference may also occur in the circuit layer 104 and the display layer 106. Therefore, the compensation operation tester 240 may compare a delta value DT of the circuit layer 104 with a threshold value TH of the circuit layer 104 or may compare a delta value DT of the display layer 106 with a threshold value TH of the display layer 106.

In an embodiment, the delta value DT may be calculated based on a production date. For example, the delta value DT may be calculated based on Feb. 1, 2024. For example, the delta value DT may be calculated based on Feb. 1, 2024, and Feb. 2, 2024.

In another embodiment, the delta value DT may be calculated based on a process time (i.e., process duration). For example, the process time may be unusual due to a stagnation, etc. Therefore, when the process time is unusual, the delta value DT may be calculated based on the process time. For example, when the process time is 1 hour or longer and less than 2 hours, the delta value DT may be calculated. For another example, when the process time is 2 hours or longer, the delta value DT may be calculated.

As such, by comparing the delta value DT calculated based on the red test data TD_R to which the red compensation data CMPD_R is applied, the green test data TD_G to which the green compensation data CMPD_G is applied, and the blue test data TD_B to which the blue compensation data CMPD_B is applied, with the threshold value TH, it may be tested whether the compensation operation is the miscompensation. Accordingly, when the compensation operation is the miscompensation, it is determined that there is the problem (e.g., the external factor of the display device 100) in the compensation operation, and thus the compensation data CMPD may not be applied to the display device 100.

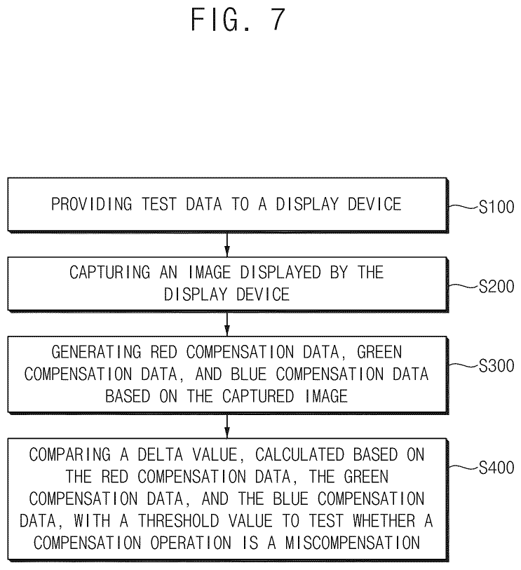

FIG. 7 is a flowchart illustrating a method of testing a compensation operation according to embodiments of the present invention.

Referring to FIGS. 1 to 7, a method of testing a compensation operation according to embodiments of the present invention may include providing test data TD including first red test data TD_R, first green test data TD_G, and first blue test data TD_B to the display device (step S100), capturing an image displayed by the display device 100 based on the test data TD (step S200), generating red compensation data CMPD_R which is compensation data CMPD for the first red test data TD_R, green compensation data CMPD_G which is compensation data CMPD for the first green test data TD_G, and blue compensation data CMPD B which is compensation data CMPD for the first blue test data TD_B based on a luminance and a color coordinates of the captured image (step S300), and comparing a delta value DT, calculated based on second red test data TD_R to which the red compensation data CMPD_R is applied, second green test data TD_G to which the green compensation data CMPD_G is applied, and second blue test data TD_B to which the blue compensation data CMPD_B is applied, with a threshold value TH to test whether the compensation operation is a miscompensation (step S400).

The comparing of the delta value DT with the threshold value TH may include determining that the compensation operation is the miscompensation when the delta value DT is greater than the threshold value TH. The comparing of the delta value DT with the threshold value TH may further include determining that the compensation operation is a normal compensation when the delta value DT is less than or equal to the threshold value TH.

The method of testing the compensation operation of FIG. 7 is substantially equal to the compensation operation test system 10 of FIG. 1. Therefore, same reference numbers are used for identical or similar components, and redundant descriptions are omitted.

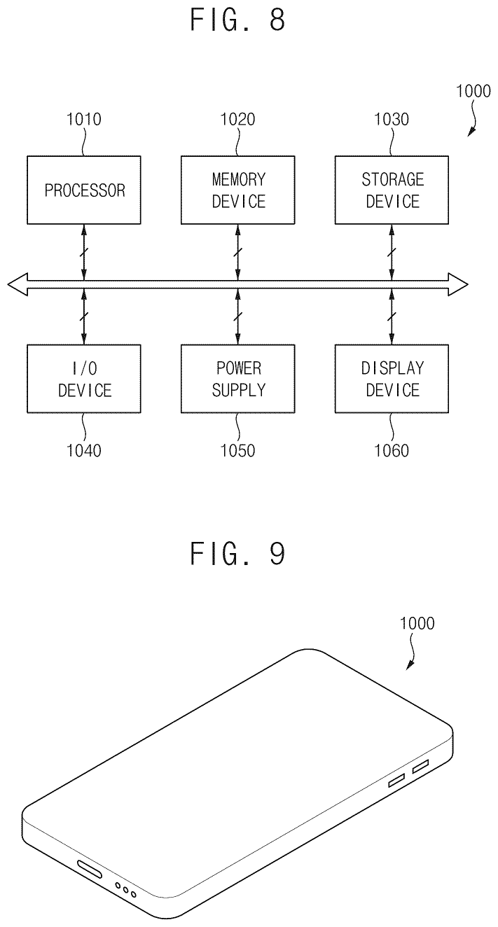

FIG. 8 is a block diagram illustrating an electronic device. FIG. 9 is a diagram illustrating an embodiment in which the electronic device of FIG. 8 is implemented as a smart phone.

Referring to FIGS. 8 and 9, the electronic device 1000 may include a processor 1010, a memory device 1020, a storage device 1030, an input/output (“I/O”) device 1040, a power supply 1050, and a display device 1060. The display device 1060 may be the display device 100 of FIG. 1. In addition, the electronic device 1000 may further include a plurality of ports for communicating with a video card, a sound card, a memory card, a universal serial bus (“USB”) device, other electronic devices, and the like.

In an embodiment, as shown in FIG. 9, the electronic device 1000 may be implemented as the smart phone. However, the electronic device 1000 is not limited thereto.

For example, the electronic device 1000 may be implemented as a cellular phone, a video phone, a smart pad, a smart watch, a tablet PC, a car navigation system, a computer monitor, a laptop, a head mounted display (“HMD”) device, and the like.

The processor 1010 may perform various computing functions. The processor 1010 may be a micro processor, a central processing unit (“CPU”), an application processor (“AP”), and the like. The processor 1010 may be coupled to other components via an address bus, a control bus, a data bus, and the like. Further, the processor 1010 may be coupled to an extended bus such as a peripheral component interconnection (“PCI”) bus.

As used in connection with various embodiments of the disclosure, each of the test data generator 210, the compensation data generator 230, and the compensation operation tester 240 may be implemented in hardware, software, or firmware, for example, implemented in a form of an application-specific integrated circuit (ASIC).

The memory device 1020 may store data for operations of the electronic device 1000. For example, the memory device 1020 may include at least one nonvolatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and the like and/or at least one volatile memory device such as a dynamic random access memory (“DRAM”) device, a static random access memory (“SRAM”) device, a mobile DRAM device, and the like.

The storage device 1030 may include a solid state drive (“SSD”) device, a hard disk drive (“HDD”) device, a CD-ROM device, and the like.

The I/O device 1040 may include an input device such as a keyboard, a keypad, a mouse device, a touchpad, a touchscreen, and the like, and an output device such as a printer, a speaker, and the like. In some embodiments, the I/O device 1040 may include the display device 1060.

The power supply 1050 may provide power for operations of the electronic device 1000.

The display device 1060 may be connected to other components through buses or other communication links.

The inventions may be applied to any display device and any electronic device including the touch panel. For example, the inventions may be applied to a mobile phone, a smart phone, a tablet computer, a digital television (“TV”), a 3D TV, a personal computer (“PC”), a home appliance, a laptop computer, a personal digital assistant (“PDA”), a portable multimedia player (“PMP”), a digital camera, a music player, a portable game console, a navigation device, etc.

The foregoing is illustrative of the invention and is not to be construed as limiting thereof. Although a few embodiments of the invention have been described, those skilled in the art will readily appreciate that many modifications are possible in the embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of the invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A method of testing a compensation operation for a display device, comprising:
providing test data including first red test data, first green test data, and first blue test data to the display device;
capturing an image displayed by the display device based on the test data;
generating red compensation data, which is compensation data for the first red test data, green compensation data, which is compensation data for the first green test data, and blue compensation data, which is compensation data for the first blue test data, based on a luminance and a color coordinates of the captured image; and
comparing a delta value, calculated based on second red test data to which the red compensation data is applied, second green test data to which the green compensation data is applied, and second blue test data to which the blue compensation data is applied, with a threshold value to test whether the compensation operation is a miscompensation.

2. The method of claim 1, wherein the delta value is a difference between a maximum value and a minimum value among the second red test data to which the red compensation data is applied, the second green test data to which the green compensation data is applied, and the second blue test data to which the blue compensation data is applied.

3. The method of claim 1, wherein the comparing of the delta value with the threshold value includes determining that the compensation operation is the miscompensation when the delta value is greater than the threshold value.

4. The method of claim 3, wherein the comparing of the delta value with the threshold value further includes determining that the compensation operation is a normal compensation when the delta value is less than or equal to the threshold value.

5. The method of claim 1, wherein the display device includes:
a substrate;
a circuit layer positioned on the substrate; and
a display layer positioned on the circuit layer.

6. The method of claim 5, wherein the delta value is a delta value of the circuit layer, and the threshold value is a threshold value of the circuit layer.

7. The method of claim 5, wherein the delta value is a delta value of the display layer, and the threshold value is a threshold value of the display layer.

8. The method of claim 1, wherein the display device is divided into cells.

9. The method of claim 8, wherein the delta value is a delta value of each of the cells, and the threshold value is a threshold value of each of the cells.

10. The method of claim 1, wherein the delta value is calculated based on a production date of the display device.

11. The method of claim 1, wherein the delta value is calculated based on a process duration of the display device.

12. A compensation operation test system, comprising:
a display device including a display panel including pixels; and
a test device configured to perform a compensation operation and test the compensation operation,
wherein the test device includes:
a test data generator configured to provide test data including first red test data, first green test data, and first blue test data to the display device;
a camera configured to capture an image displayed by the display device based on the test data;
a compensation data generator configured to generate red compensation data, which is compensation data for first the red test data, green compensation data, which is compensation data for the first green test data, and blue compensation data, which is compensation data for the first blue test data, based on a luminance and a color coordinates of the captured image; and
a compensation operation tester configured to compare a delta value, calculated based on second red test data to which the red compensation data is applied, second green test data to which the green compensation data is applied, and second blue test data to which the blue compensation data is applied, with a threshold value to test whether the compensation operation is a miscompensation.

13. The compensation operation test system of claim 12, wherein the delta value is a difference between a maximum value and a minimum value among the second red test data to which the red compensation data is applied, the second green test data to which the green compensation data is applied, and the second blue test data to which the blue compensation data is applied.

14. The compensation operation test system of claim 12, wherein the compensation operation tester is configured to determine that the compensation operation is the miscompensation when the delta value is greater than the threshold value.

15. The compensation operation test system of claim 14, wherein the compensation operation tester is configured to determine that the compensation operation is a normal compensation when the delta value is less than or equal to the threshold value.

16. The compensation operation test system of claim 12, wherein the display device includes:
a substrate;
a circuit layer positioned on the substrate; and
a display layer positioned on the circuit layer.

17. The compensation operation test system of claim 16, wherein the delta value is a delta value of the circuit layer, and the threshold value is a threshold value of the circuit layer.

18. The compensation operation test system of claim 16, wherein the delta value is a delta value of the display layer, and the threshold value is a threshold value of the display layer.

19. The compensation operation test system of claim 12, wherein the display device is divided into cells.

20. The compensation operation test system of claim 19, wherein the delta value is a delta value of each of the cells, and the threshold value is a threshold value of each of the cells.
